(19) United States
(12) Patent Application Publication
(10) Pub. No.: US 2026/0016503 A1
(43) Pub. Date: Jan. 15, 2026

(54) PROBE APPARATUS

(71) Applicant: Kabushiki Kaisha Nihon Micronics, Tokyo (JP)

(72) Inventor: Tomoaki KUGA, Aomori (JP)

(21) Appl. No.: 18/992,880

(22) PCT Filed: Jun. 16, 2023
(86) PCT No.: PCT/JP2023/022457

§ 371 Date: Jan. 9, 2025

(30) Foreign Application Priority Data
Jul. 14, 2022 (JP) 2022-112859

(51) Int. Cl. G01R 1/067

(52) U.S. Cl. CPC G01R 1/06755; G01R 1/06716

(57) ABSTRACT

A probe apparatus includes: a housing; a probe that has a first contact portion and a second contact portion and is supported by the housing, and in which at least either the first contact portion or the second contact portion is made of a conductive ceramic material; and an elastic portion that is arranged inside the housing by abutting on the probe and the housing. A posture of the probe changes inside the housing such that a position of a contact region in the second contact portion in contact with an electrode pad changes in response to a displacement of the first contact portion. The elastic portion is elastically deformed in response to a change in the posture of the probe inside the housing, and biases the probe in a direction that cancels the displacement of the first contact portion.

### TECHNICAL FIELD

The present invention relates to a probe apparatus used for inspecting the electrical characteristics of a device.

### BACKGROUND

In inspecting the electrical characteristics of a device in which a semiconductor integrated circuit or the like is mounted on a package, a probe apparatus for electrically connecting a device and an inspection device has been used. The probe apparatus electrically connects an electrode terminal of the device and an electrode pad arranged on a substrate such as a printed circuit board (PCB). The electrode pad is electrically connected to the inspection device via a wiring pattern or the like formed on the substrate.

### CITATION LIST

### Patent Literature

Patent Literature 1: JP 2019-35660 A

### SUMMARY OF THE INVENTION

### Technical Problem

In a probe apparatus, an electrode terminal and an electrode pad are electrically connected with each other by a contactor that comes into contact with the electrode terminal and the electrode pad. The contactor is made of metal that is a conductive material. However, when the contactor comes into contact with the electrode terminal and the electrode pad, the material of the electrode terminal and the electrode pad adheres to the surface of the contactor, thereby decreasing the contactability of the contactor with the electrode terminal and the electrode pad (hereinafter, it is simply referred to as “contactability”).

In order to restore the contactability of the contactor, it is necessary to perform cleaning work to remove the metal adhering to the surface of the contactor. In cleaning work, for example, the metal adhering to the surface of the contactor is removed by a brush or a cleaning sheet. However, due to mechanical cleaning work using a brush or a cleaning sheet, the contactor is abraded, thereby reducing the contactability.

An object of the present invention is to provide a probe apparatus capable of suppressing a reduction in contactability with an electrode terminal and an electrode pad.

### Technical Solution

A probe apparatus according to an aspect of the present invention includes: a housing that has a first surface and a second surface; a probe that has a first contact portion exposed on the first surface and a second contact portion exposed on the second surface, and in which at least either the first contact portion or the second contact portion is made of a conductive ceramic material; and an elastic portion that is arranged inside the housing by abutting on the probe and the housing. A posture of the probe changes inside the housing such that a position of a contact region in the second contact portion in contact with the electrode pad changes in response to a displacement of the first contact portion. An elastic portion is elastically deformed in response to a change in the posture of the probe inside the housing, and biases the probe in a direction that cancels the displacement of the first contact portion.

### Effect of the Invention

The present invention makes it possible to provide a probe apparatus capable of suppressing a reduction in contactability with an electrode terminal and an electrode pad.

### BRIEF DESCRIPTION OF DRAWINGS

FIG. 1 is a schematic diagram illustrating a configuration of a probe apparatus according to a first embodiment.

FIG. 2 is a schematic diagram illustrating a change in posture of a probe of the probe apparatus according to the first embodiment.

FIG. 3 is a table illustrating hardness and volume resistivity of materials.

FIG. 4 is a schematic diagram illustrating a configuration of a probe apparatus according to a second embodiment.

FIG. 5 is a schematic diagram for explaining a method of manufacturing the probe apparatus according to the second embodiment.

FIG. 6 is a schematic diagram illustrating a configuration of a probe apparatus according to a third embodiment.

FIG. 7 is a schematic diagram for explaining a method of manufacturing the probe apparatus according to the third embodiment.

FIG. 8 is a schematic diagram illustrating an arrangement example of probes in a probe apparatus of a comparative example.

### DETAILED DESCRIPTION OF THE INVENTION

Embodiments of the present invention will be described below with reference to the drawings. The same or similar elements illustrated in the drawings are denoted by the same or similar reference numerals. However, the drawings are illustrated schematically, and it should be noted that the proportions of the thicknesses or lengths of the respective parts and so forth are not drawn to scale. It should also be understood that the relationships or proportions of the dimensions between the respective drawings are different from each other in some elements. The embodiments described below exemplify a device and a method for embodying the technical idea of the present invention. In the embodiments of the present invention, the material, shape, structure, arrangement, manufacturing method and the like of the components are not limited to the following description.

### First Embodiment

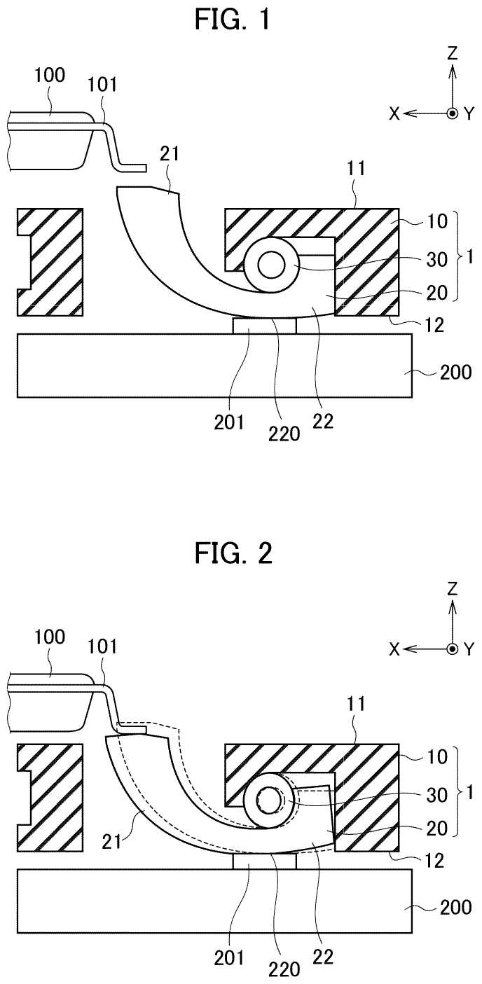

A probe apparatus 1 according to a first embodiment illustrated in FIG. 1 is used for inspecting the electrical characteristics of a device 100 to be inspected. The device 100 is an inspection object in which a semiconductor integrated circuit or the like is mounted on a package. The probe apparatus 1 electrically connects an electrode terminal 101 of the device 100 and an electrode pad 201 of a substrate 200. FIG. 1 exemplifies a case where the electrode terminal 101 is a lead electrode of the package. The electrode pad 201 is electrically connected to an inspection device via a wiring pattern (not illustrated) formed on the substrate 200.

The probe apparatus 1 includes a housing 10 having a first surface 11 and a second surface 12 facing the first surface 11, a conductive probe 20 having a first contact portion 21 and a second contact portion 22 and supported by the housing 10, and an elastic portion 30 arranged inside the housing 10. The probe 20 functions as a contactor for electrically connecting the electrode terminal 101 and the electrode pad 201. In the following description, when each of the first contact portion 21 and the second contact portion 22 is not limited, they will be referred to as a contact portion. In the probe 20, at least the first contact portion 21 in contact with the electrode terminal 101 and the second contact portion 22 in contact with the electrode pad 201 are made of conductive ceramic materials. A conductive material such as a metal material is used for a part of the probe 20 that is not made of a conductive ceramic material. For example, the probe 20 may have a structure in which a metal material such as a beryllium copper (Be—Cu) material or a palladium (Pd) alloy material is used as a material for a portion between the first contact portion 21 and the second contact portion 22 which are made of conductive ceramic materials. Alternatively, not only the contact portion, but also the whole probe 20 may be made of a conductive ceramic material. Hereinafter, a case in which the whole probe 20 is made of a conductive ceramic material will be described by way of example. The elastic portion 30 is arranged inside the housing 10 by abutting on the housing 10 and the probe 20.

In order to make the operation of the probe apparatus 1 easier to understand, the X direction, the Y direction, and the Z direction are defined as illustrated in FIG. 1. In FIG. 1, the X direction is a left-right direction in the page space, the Y direction is a depth direction in the page space, and the Z direction is an up-down direction in the page space. Further, in the Z direction, the direction in which the device 100 is positioned as viewed from the probe apparatus 1 is an upward direction, and the direction in which the probe apparatus 1 is positioned as viewed from the device 100 is a downward direction.

Although only one probe 20 of the probe apparatus 1 is illustrated in FIG. 1, the probe apparatus 1 may have a plurality of probes 20. For example, the probe apparatus 1 may have a configuration in which a plurality of probes 20 are arranged along the Y direction. The thickness of the probe 20 in the Y direction (hereinafter, it is also simply referred to as “thickness”) is, for example, about 0.1 to 0.2 mm. The thickness of the probe 20 is not limited to 0.1 to 0.2 mm and can be arbitrarily set according to the size and spacing of the electrode terminals 101, the magnitude of a current flowing through the probe 20 at the time of inspection of the device 100, and the like. For example, the probe 20 may be formed by punching a plate made of a conductive ceramic material into a predetermined shape by means of a wire discharge method, a laser processing method, or the like. For this reason, the processing accuracy of the probe 20 in thickness can be improved compared to forming the probe 20 by processing a metal material. That is, the probe 20 made of a conductive ceramic material hardly causes processing variations in the thickness of the probe 20. In contrast, since a metal material is softer than a conductive ceramic material, the probe 20 made of a metal material tends to cause processing variations in the thickness of the probe 20.

In FIG. 1, the probe apparatus 1 is arranged in the downward direction of the device 100 as viewed from the Z direction. The first contact portion 21 of the probe 20 is exposed on the first surface 11 of the housing 10, and the second contact portion 22 of the probe 20 is exposed on the second surface 12 of the housing 10. The probe 20 is arranged in the housing 10 such that the first contact portion 21 and the electrode terminal 101 of the device 100 come into contact with each other when the spacing between the probe apparatus 1 and the device 100 becomes narrow along the Z direction. Further, the probe apparatus 1 is arranged in the housing 10 such that the contact region 220 of the second contact portion 22 comes into contact with the electrode pad 201 of the substrate 200. As will be described later, at the time of inspection of the device 100, a position of the contact region 220 in the second contact portion 22 in contact with the electrode pad 201 changes due to the change in the position of the first contact portion 21 in the Z direction.

When viewed from the Y direction, the probe 20 has a curved shape in which a recess facing upward is formed. One end of the probe 20 positioned away from the outer portion of the probe 20 (hereinafter, it is referred to as a “curved portion”) facing the recess is the first contact portion 21. The other end of the probe 20 close to the recess is the second contact portion 22. A part of the arc-shaped region at the outer edge of the curved portion is the contact region 220. When the XY plane defined by the X direction and the Y direction is the projection plane, the projection line in the direction connecting the first contact portion 21 and the second contact portion 22 (hereinafter, it is referred to as “extending direction” of the probe 20) extends in the X direction. In other words, the probe 20 extends in the X direction when viewed from the Z direction.

The elastic portion 30 has a cylindrical shape in which an axial direction extends in the Y direction. That is, the axial direction of the elastic portion 30 is perpendicular to the direction in which the first contact portion 21 of the probe 20 is displaced and perpendicular to the direction in which the probe 20 extends. The elastic portion 30 abuts on the inner side of the recess of the probe 20. In other words, the elastic portion 30 is sandwiched between the surface of the recess of the probe 20 and the inner wall of the housing 10.

At the time of inspection of the device 100, as illustrated in FIG. 2, the electrode terminal 101 of the device 100 and the electrode pad 201 of the substrate 200 are electrically connected with each other by the conductive probe 20. That is, at the time of inspection of the device 100, the device 100 is moved relative to the probe apparatus 1 in the Z direction, thereby pressing the first contact portion 21 of the probe 20 against the electrode terminal 101 of the device 100. At this time, a posture of the probe 20 changes inside the housing 10 in a state in which the second contact portion 22 is in contact with the surface of the electrode pad 201 due to the pressing force applied to the first contact portion 21 between the first contact portion 21 and the electrode terminal 101.

Specifically, in response to the displacement of the first contact portion 21 in the Z direction caused by the pressing force applied to the first contact portion 21, a posture of the probe 20 changes inside the housing 10 while maintaining the state in which the second contact portion 22 is in contact with the electrode pad 201. As a posture of the probe 20 changes, the position of the contact region 220 in the second contact portion 22 in contact with the electrode pad 201 changes. In FIG. 2, the posture of the probe 20 and the shape of the elastic portion 30 in the state in which the first contact portion 21 and the electrode terminal 101 are in contact with each other (hereinafter, it is also referred to as “contact state”) are illustrated by solid lines. In FIG. 2, the posture of the probe 20 and the shape of the elastic portion 30 in the state in which the first contact portion 21 and the electrode terminal 101 are not in contact with each other (hereinafter, it is also referred to as “non-contact state”) are illustrated by dashed lines. In the contact state at the time of inspection of the device 100, a posture of the probe 20 changes such that the position of the contact region 220 is closer to the first contact portion 21 than in the non-contact state.

The probe 20 requires conductivity for electrically connecting the electrode terminal 101 and the electrode pad 201, and mechanical strength that does not change in shape between the contact state and the non-contact state. The probe 20 made of a conductive ceramic material has both conductivity and mechanical strength.

In the contact state, the elastic portion 30 is sandwiched between the probe 20 and the housing 10 and compressed, in response to the change in the posture of the probe 20 inside the housing 10. That is, in the contact state, the elastic portion 30 is elastically deformed. The elastically deformed elastic portion 30 biases the probe 20 in the direction in which the posture of the probe 20 returns to the posture in the non-contact state. In other words, the elastic portion 30 biases the probe 20 in such a way as to press the first contact portion 21 against the electrode terminal 101.

During the inspection of the device 100, the state in which the first contact portion 21 abuts on the electrode terminal 101 and the second contact portion 22 abuts on the electrode pad 201 is maintained by an elastic force of the elastic portion 30. Thus, at the time of inspection of the device 100, the electrical connection between the electrode terminal 101 of the device 100 and the electrode pad 201 of the substrate 200 is ensured via the probe 20.

In the probe apparatus 1, as the contact region 220, a part of the arc-shaped region at the outer edge of the curved portion of the probe 20 comes into contact with the electrode pad 201 in a line extending in the Y direction. As illustrated in FIG. 2, the position of the contact region 220 in the contact state is closer to the first contact portion 21 than the position of the contact region 220 in the non-contact state. The position of the contact region 220 changes between the contact state and the non-contact state, since the position of the contact region 220 changes along the outer edge of the curved portion according to the change in the posture of the probe 20. The contact region 220 is included in the arc-shaped region of the curved portion, and thus the position of the contact region 220 in contact with the electrode pad 201 changes smoothly according to the change in the posture of the probe 20. For this reason, even if a posture of the probe 20 changes, damage to the second contact portion 22 and the electrode pad 201 can be suppressed.

As described above, at the time of inspection of the device 100, the elastic portion 30 sandwiched between the probe 20 and the housing 10 is elastically deformed by the change in the posture of the probe 20. The elastic portion 30 then biases the probe 20 such that the first contact portion 21 comes into contact with the electrode terminal 101 of the device 100 with a predetermined pressing force. That is, the elastic portion 30 biases the probe 20 in a direction that cancels the displacement of the first contact portion 21 caused by the pressing force applied to the first contact portion 21 when the first contact portion 21 is pressed against the electrode terminal 101. During the inspection of the device 100, that is, while the first contact portion 21 is in contact with the electrode terminal 101, the elastic portion 30 is in a compressively deformed state.

After the inspection of the device 100 is completed, the position of the device 100 relative to the probe apparatus 1 in the Z direction is changed so as to increase the spacing between the device 100 and the probe apparatus 1. By separating the electrode terminal 101 of the device 100 from the first contact portion 21 of the probe 20, the pressing force applied to the first contact portion 21 is eliminated. As a result, the shape of the elastic portion 30 returns to the non-contact state, and the posture of the probe 20 returns to the non-contact state due to the elastic force of the elastic portion 30.

The probe 20 is supported in the housing 10 such that the posture of the probe 20 can be changed in response to the displacement of the position of the first contact portion 21 in the Z direction. A posture of the probe 20 changes inside the housing 10 such that the position of the contact region 220 in the second contact portion 22 in contact with the electrode pad 201 changes in response to the displacement of the first contact portion 21 in the Z direction. For example, although not illustrated, a part of the probe 20 may be protruded and the protruded part of the probe 20 may be fitted into a support hole provided in the housing 10. Alternatively, a part of the probe 20 may be placed in a support portion of the housing 10 provided in the downward direction of the probe 20.

As described above, the probe apparatus 1 includes the probe 20 made of a conductive ceramics material which simultaneously comes into contact with the electrode terminal 101 and the electrode pad 201, and the elastic portion 30 which biases the probe 20 by an elastic force when the probe 20 is in contact with the electrode terminal 101. The contact load applied to the probe 20 when the probe 20 and the electrode terminal 101 come into contact with each other is controlled by the elastic force of the elastic portion 30. The contact load increases by increasing the elastic force of the elastic portion 30, and the contact load decreases by decreasing the elastic force of the elastic portion 30. Further, in the probe apparatus 1, the amount (hereinafter, it is also referred to as “stroke”) by which the first contact portion 21 is displaced by coming into contact with the electrode terminal 101 is controlled by the elastic force of the elastic portion 30. That is, the stroke decreases by increasing the elastic force of the elastic portion 30, and the stroke increases by decreasing the elastic force of the elastic portion 30.

For example, elastomer is used as the material of the elastic portion 30. The elastic portion 30 may have a cylindrical shape having a hollow structure. By forming the elastic portion 30 into a cylindrical shape, the magnitude of the contact load and stroke can be easily controlled. That is, by increasing the cylindrical elastic portion 30 in thickness, the contact load can be increased and the stroke can be decreased. In contrast, by decreasing the cylindrical elastic portion 30 in thickness, the contact load can be decreased and the stroke can be increased.

The elastic portion 30 may be made of a conductive material or an insulating material. However, the materials used for the housing 10 and the elastic portion 30, and the arrangement of the elastic portion 30 inside the housing 10 are set in such a way that the probes 20 are electrically insulated from each other.

Conventionally, a metal material has been used for a contactor to electrically connect the electrode terminal 101 and the electrode pad 201. The contactor corresponds to the probe 20 in the probe apparatus 1. By repeating the inspection of the device 100, the metal material (such as tin or nickel palladium (Ni—Pd)) of the electrode terminal 101 and the electrode pad 201 adheres to the surface of the contactor. In order to prevent the contactability of the contactor with the electrode terminal 101 and the electrode pad 201 from deteriorating, it is necessary to remove the metal adhering to the surface of the contactor by cleaning work. However, the surface of the contactor is abraded or damaged by cleaning work, thereby deteriorating the contactability of the contactor.

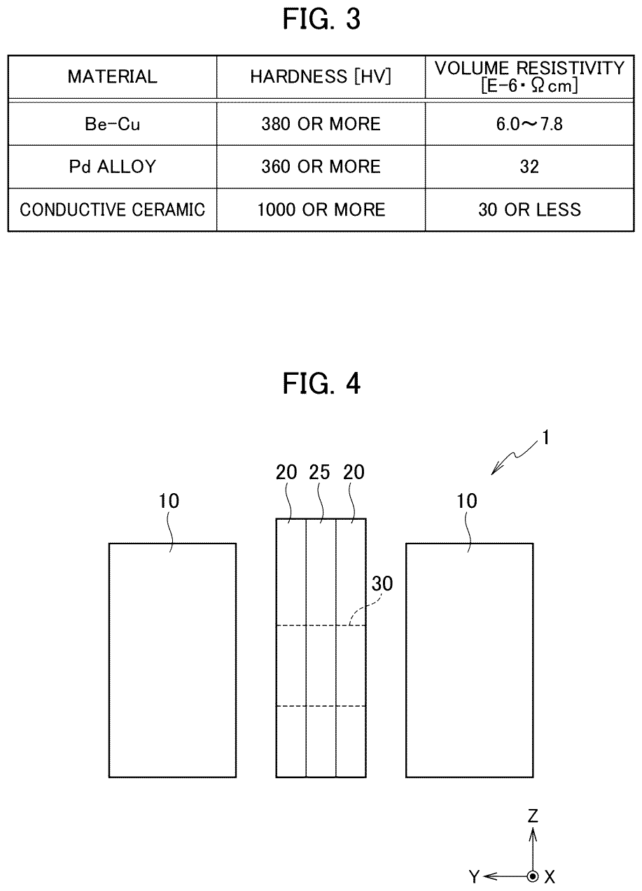

In contrast, in the probe apparatus 1, the deterioration of the contactability of the probe 20 can be suppressed by using a conductive ceramic material having higher hardness and wear resistance than a metal material as the material of the probe 20. For example, according to the probe apparatus 1, the abrasion of the probe 20 caused by cleaning work for removing the metal adhering to the surface of the probe 20 can be suppressed. Accordingly, according to the probe apparatus 1, the probe 20 can be in stable contact with the electrode terminal 101 and the electrode pad 201. FIG. 3 illustrates a table comparing the hardness and volume resistivity of beryllium copper (Be—Cu) material and palladium (Pd) alloy material, which are a typical metal material of a contactor, and a conductive ceramic material. As illustrated in FIG. 3, the hardness of the conductive ceramic material is higher than that of the metal material, and the volume resistivity of the conductive ceramic material is equal to or lower than that of the metal material. Thus, the conductive ceramic material can be suitably used as the material of the probe 20.

For example, the hardness of the probe 20 is preferably set to 1400 HV or more. Further, the hardness of the probe 20 is preferably set to such a degree that ensures a predetermined toughness for preventing damage such as a chip caused by an external force applied to the probe 20 at the time of inspection. For example, when the hardness of the probe 20 is set to 1000 HV or more, the hardness is higher than that of a metal material generally used for a probe, thereby obtaining an effect in which the probe 20 is less likely to be damaged at the time of cleaning. The metal material generally used for a probe may be, for example, Be-Cu (about 380 HV), a palladium alloy (360 HV), or rhenium tungsten (900 HV), all of which have a hardness lower than 1000 HV.

In addition, for example, the volume resistivity of the probe 20 is preferably set to 10 μΩ·cm or less. For example, when the volume resistivity of the probe 20 is set to 30 μΩ·cm or less, the probe 20 may have a volume resistivity equivalent to that of a metal material (palladium alloy (32 μΩ·cm)) generally used for a probe. Accordingly, by using a conductive ceramic material for the probe 20, an effect can be obtained that suppresses abrasion at the time of cleaning and extends the life of the probe 20 while ensuring the electrical characteristics equivalent to those of a metal material.

In addition, the conductive ceramic material used for the probe 20 is preferably a material having a hardness higher than that of the electrode terminal 101 and the electrode pad 201. By making the hardness of the probe 20 higher than that of the electrode terminal 101 and the electrode pad 201, it is possible to suppress an abrasion damage of the first contact portion 21 and the second contact portion 22 of the probe 20 due to repeated inspection of the device 100.

Meanwhile, when a contactor is made of a metal material, metal plating is applied to the surface of the contactor made of the metal material in some cases in order to improve the contactability of the contactor. For example, the contactor is used in which gold plating is applied to the surface of a base material made of a metal material such as a Be-Cu material or a palladium alloy material. However, a problem may arise when using the contactor with metal plating on the surface to inspect the device 100. For example, the metal plating peeled off from the contactor by coming into contact with the electrode terminal 101 and the electrode pad 201 adheres to the surface of the substrate 200, thereby causing a short circuit between the electrode pads 201. In contrast, the surface of the probe 20 of the probe apparatus 1 is not metal-plated, and the conductive ceramic material comes into contact with the electrode terminal 101 in the first contact portion 21, and the conductive ceramic material comes into contact with the electrode pad 201 in the second contact portion 22. This makes it possible to prevent a short circuit in the substrate 200 due to peeling of the metal plating from the surface of the probe 20.

As described above, in the probe apparatus 1 according to the first embodiment, the probe 20 made of a conductive ceramic material is used, which has a conductivity equal to or higher than that of the metal material, and has a higher hardness and a higher wear resistance than that of the metal material. Since at least a part of the probe 20 that comes into contact with the electrode terminal 101 and the electrode pad 201 is made of a conductive ceramic material, abrasion of the contacting part is suppressed. Accordingly, the probe apparatus 1 makes it possible to suppress a decrease in the contactability with the electrode terminal 101 and the electrode pad 201, thereby making it possible to inspect the electrical characteristics of the device 100 accurately. Not only when the whole probe 20 is made of a conductive ceramic material, but also when at least the first contact portion 21 and the second contact portion 22 of the probe 20 are made of a conductive ceramic material, it is possible to suppress a decrease in the contactability with the electrode terminal 101 and the electrode pad 201.

### Second Embodiment

In the probe apparatus 1 according to a second embodiment, as illustrated in FIG. 4, two probes 20 are arranged in parallel along the Y direction with a shield plate 25 made of an insulating material therebetween. FIG. 4 illustrates a configuration of the probe apparatus 1 as viewed from the X direction, with the elastic portion 30 indicated by dashed lines transmitted through the probe 20 and the shield plate 25. The probe apparatus 1 illustrated in FIG. 4 differs from that of the first embodiment in that two probes 20 are arranged along the Y direction with the shield plate 25 therebetween. The probe apparatus 1 according to the second embodiment is the same as that of the first embodiment in other configurations. A pair of probes 20 arranged with the shield plate 25 therebetween is also hereinafter referred to as a “probe pair”.

In the probe apparatus 1 illustrated in FIG. 4, the spacing in the Y direction between the first contact portions 21 of the two probes 20 constituting the probe pair is determined by the thickness of the shield plate 25 in the Y direction (hereinafter, it is referred to as “plate thickness”). According to the probe apparatus 1 having the probe pair, the first contact portions 21 of the probes 20 can be independently brought into contact with the two electrode terminals 101 arranged close to each other. The thickness of the shield plate 25 may be set according to the spacing of the electrode terminals 101 in the Y direction.

According to the probe apparatus 1 illustrated in FIG. 4, the probe pair can be Kelvin-connected to the device 100. In other words, the probe apparatus 1 having the probe pair can be used as a Kelvin contact measuring apparatus.

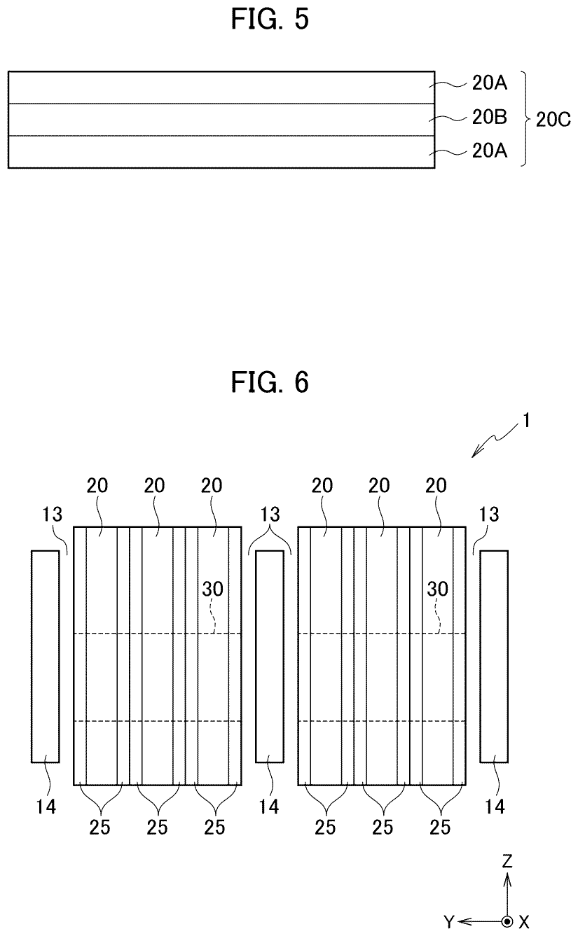

For example, as illustrated in FIG. 5, the probe pair may be manufactured by processing a sheet material 20C in which an insulating ceramic material 20B is sandwiched from both sides using conductive ceramic materials 20A. The sheet material 20C is punched into a predetermined shape of the probe 20 by a wire discharge method, a laser processing method, or the like. Using the above process, the probe pair having the shield plate 25 formed by processing the insulating ceramic material 20B and the probe 20 formed by processing the conductive ceramic materials 20A is manufactured. The sheet material 20C may be formed by diffusion bonding of the insulating ceramic material 20B and the conductive ceramic materials 20A. In a case where the bonding temperature of the diffusion bonding is at a high temperature of 800 degrees or more, it is preferable that a thermal expansion coefficient of the insulating ceramic material 20B and a thermal expansion coefficient of the conductive ceramic materials 20A be close to each other so as not to cause cracking or deformation in the sheet material 20C when the sheet material is cooled to normal temperature after bonding.

The spacing between the probes 20 of the probe pair is determined by the thickness of the shield plate 25 made of an insulating ceramic material. Thus, according to the probe apparatus 1 illustrated in FIG. 4, the probe apparatus 1 can be manufactured in which the spacing between the probes 20 is set with high accuracy.

As described above, the probe apparatus 1 according to the second embodiment makes it possible to improve the contactability of the probes 20 by using a high hardness conductive ceramic material as the material of the probes 20, and set the spacing between the probes 20 with high accuracy. In other respects, the probe apparatus 1 according to the second embodiment is substantially the same as the probe apparatus 1 according to the first embodiment, and a redundant description thereof will be omitted. For example, only the contact portions of the probes 20 may be made of a conductive ceramic material, or the whole probes 20 may be made of a conductive ceramic material.

### Third Embodiment

In the probe apparatus 1 according to the third embodiment, as illustrated in FIG. 6, the probe 20 is sandwiched from both sides by the shield plates 25 made of an insulating material. A plurality of probes 20 with which the shield plates 25 are brought into mutual contact are arranged in parallel in the Y direction inside one slit 13 provided in the housing 10. FIG. 6 illustrates a configuration of the probe apparatus 1 as viewed from the X direction, with the elastic portions 30 indicated by dashed lines transmitted through the probes 20 and the shield plates 25. The probe apparatus 1 illustrated in FIG. 6 differs from that of the first embodiment in that the probe 20 is sandwiched between the shield plates 25 and the plurality of probes 20 are arranged in the same slit 13 of the housing 10. The probe apparatus 1 according to the third embodiment is the same as that of the first embodiment in other configurations. The whole plurality of probes 20 connected to each other via the shield plates 25 are also hereinafter referred to as a “probe group”. The probe apparatus 1 illustrated in FIG. 6 exemplarily illustrates a case where one probe group includes three probes 20. The number of probes 20 constituting the probe group can be optionally set.

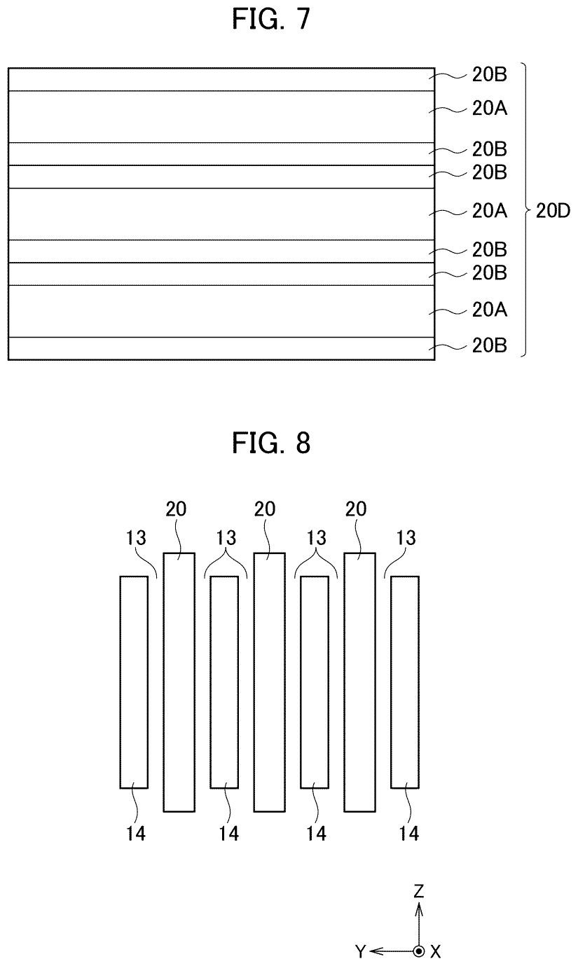

For example, as illustrated in FIG. 7, the probe group may be manufactured by processing a stacked material 20D formed by stacking a structure in which the conductive ceramic material 20A is sandwiched from both sides by the insulating ceramic materials 20B. The stacked material 20D is punched into a predetermined shape of the probe 20 by a wire discharge method, a laser beam processing method, or the like. Using the above process, the probe group having a plurality of probes 20 is manufactured. By processing the stacked material 20D, the plurality of probes 20 can be manufactured in one processing process.

In a probe apparatus of a comparative example in which the probes 20 are not sandwiched by the insulating shield plates 25, as illustrated in FIG. 8, one probe 20 is disposed in one slit 13 of the housing 10. By disposing one probe 20 in one slit 13, a short circuit between the probes 20 is prevented by a guide portion 14 of the housing 10 separating the slits 13.

In contrast, in the probe apparatus 1 having a probe group, as illustrated in FIG. 6, a plurality of probes 20 can be arranged in one slit 13. For this reason, the probe apparatus 1 can be reduced in size. Since the spacing between the probes 20 in the probe group can be set by a thickness of the shield plate 25, the accuracy of the spacing between the probes 20 and the accuracy of the size of the whole probe group can be easily managed.

Further, since the outer side of the probes 20 in the probe group is covered with the insulating shield plate 25, the guide portion 14 of the housing 10 arranged on both sides of the slits 13 may be conductive. In other words, the housing 10 may be made of a conductive material. For this reason, the housing 10 may be set to a predetermined potential. For example, the housing 10 may be set to the ground potential by using a conductive material for the housing 10 in a case where a highly accurate inspection can be performed by setting the housing 10 to the ground potential in a device inspection. In addition, the manufacturing cost of the probe apparatus 1 can be reduced by selecting either a conductive material or an insulating material, whichever is lower in cost, as the material of the housing 10 and the elastic portion 30.

As described above, the probe apparatus 1 according to the third embodiment makes it possible to improve the contactability of the probes 20 by using a conductive ceramic material having a high hardness as the material of the probes 20, and set the spacing between the probes 20 with high accuracy. Further, the probe apparatus 1 according to the third embodiment allows for a greater selection of materials for the parts around the probes 20, thereby reducing the cost and improving the functionality. In other respects, the probe apparatus 1 according to the third embodiment is substantially the same as that of the first embodiment, and a redundant description thereof will be omitted. For example, only the contact portions of the probes 20 may be made of a conductive ceramic material, or the whole probes 20 may be made of a conductive ceramic material.

### Other Embodiments

The embodiments of the present invention have been described above, but the statements and drawings forming part of this disclosure should not be understood as limiting the invention. Various alternative embodiments, examples, and operating techniques will be apparent to those skilled in the art from this disclosure.

For example, although the case where the first contact portion 21 and the second contact portion 22 are made of a conductive ceramic material has been described above, either the first contact portion 21 or the second contact portion 22 may be made of a conductive ceramic material. For example, if either the first contact portion 21 or the second contact portion 22 is abraded by cleaning work, only the contact portion abraded by cleaning work may be made of a conductive ceramic material. That is, the electrical characteristics of the device 100 can be accurately inspected by the probe 20 in which at least either the first contact portion 21 or the second contact portion 22 is made of a conductive ceramic material.

For example, although the case where the elastic portion 30 has a cylindrical shape has been described above as an example, the elastic portion 30 is not limited to having a cylindrical shape. For example, the elastic portion 30 may have a columnar shape without a hollow portion, or the outer edge of the elastic portion 30 as viewed from the Y direction may have a polygonal shape instead of a circular shape. Further, although the case where the electrode terminal 101 of the device 100 is a lead electrode has been described above as an example, the electrode terminal 101 may be a pad electrode, a bump electrode, or an electrode having a shape other than a pad electrode and a bump electrode.

Thus, the present invention will of course include various embodiments and the like which are not described herein.

### REFERENCE SIGNS LIST

1: Probe apparatus
10: Housing
11: First surface
12: Second surface
13: Slit
14: Guide portion
20: Probe
21: First contact portion
22: Second contact portion
25: Shield plate
30: Elastic portion
100: Device
101: Electrode terminal
200: Substrate
201: Electrode pad

1. A probe apparatus that electrically connects an electrode terminal of a device to be inspected and an electrode pad connected to an inspection device, the probe apparatus comprising:
a housing that has a first surface and a second surface facing the first surface;
a probe that has a first contact portion exposed on the first surface and a second contact portion exposed on the second surface and is supported by the housing, and in which at least either the first contact portion or the second contact portion is made of a conductive ceramic material, a posture of the probe changing inside the housing such that a position of a contact region in the second contact portion in contact with the electrode pad changes in response to a displacement of the first contact portion; and
an elastic portion that is arranged inside the housing by abutting on the probe and the housing, elastically deformed in response to a change in the posture of the probe inside the housing, and biases the probe in a direction that cancels the displacement of the first contact portion.

2. The probe apparatus according to claim 1, wherein the whole probe is made of a conductive ceramic material.

3. The probe apparatus according to claim 1, wherein the probe has a curved shape, and the contact region is included in an outer arc-shaped region of the curved shape.

4. The probe apparatus according to claim 1, wherein the probe has a higher hardness than that of a probe formed by rhenium tungsten.

5. The probe apparatus according to claim 1, wherein two probes are arranged in parallel with a shield plate made of an insulating material therebetween.

6. The probe apparatus according to claim 1, wherein
the probe is sandwiched from both sides by shield plates made of an insulating material, and
a plurality of probes with which the shield plates are brought into mutual contact are arranged in parallel inside one slit provided in the housing.
